(19) United States
(12) Patent Application Publication
(10) Pub. No.: US 2025/0369119 A1
(43) Pub. Date: Dec. 4, 2025

(54) METHODS AND APPARATUS FOR THERMAL UNIFORMITY

(71) Applicant: ASM IP Holding B.V., Almere (NL)

(72) Inventors: Jinglun Li, Chandler, AZ (US); Akanksha Harish, Phoenix, AZ (US); Changyu Meng, Chandler, AZ (US); Shuyang Zhang, Chandler, AZ (US); Kyle Fondurulia, Phoenix, AZ (US)

(21) Appl. No.: 19/223,602

(22) Filed: May 30, 2025

Related U.S. Application Data
(60) Provisional application No. 63/654,219, filed on May 31, 2024.

(51) Int. Cl. C23C 16/455

(52) U.S. Cl. CPC C23C 16/4557; C23C 16/45565; C23C 16/45572

(57) ABSTRACT

Various embodiments of the present technology may provide a gas distribution system having a top portion and a bottom portion. The top portion contains a cooling ring with a channel, a first heating ring above the showerhead region, a second heating element along an edge of the top portion, a third heating element along an edge of the top portion. The bottom portion contains a plurality of heating elements arranged along the perimeter of bottom portion, radially outwards from the showerhead region.

### CROSS-REFERENCE TO RELATED APPLICATIONS

This application is a nonprovisional of, and claims priority to and the benefit of, U.S. Provisional Patent Application No. 63/654,219, filed May 31, 2024 and entitled “METHODS AND APPARATUS FOR THERMAL UNIFORMITY,” which is hereby incorporated by reference herein.

### FIELD OF INVENTION

The present disclosure generally relates to a method and apparatus for thermal uniformity. More particularly, the present disclosure relates to gas distribution plate having a cooling apparatus, multiple heating zones, and a thermal break, and a showerhead plate having multiple heating elements at the edge of the showerhead plate.

### BACKGROUND OF THE TECHNOLOGY

Thermal uniformity in reaction chambers used in semiconductor manufacturing is a factor that affects the quality and thickness of the films deposited on a wafer in a reaction chamber. Accordingly, it may be desired to heat and cool various areas of the reaction chamber to obtain a desired thermal profile.

### SUMMARY OF THE INVENTION

Various embodiments of the present technology may provide a gas distribution system having a top portion and a bottom portion. The top portion contains a cooling ring with a channel, a first heating ring above the showerhead region, a second heating element along an edge of the top portion, a third heating element along an edge of the top portion. The bottom portion contains a plurality of heating elements arranged along the perimeter of bottom portion, radially outwards from the showerhead region.

According to one aspect, an apparatus, comprises a top portion comprising: a top surface and a bottom surface; an inlet extending between the top surface and the bottom surface; an exhaust plenum surrounding the inlet; and a thermal system embedded within the top portion and comprising: a first heating element arranged in a circular pattern concentric with the inlet; a second heating element arranged along an edge of the top portion; and a third heating element opposite the second heating element along the edge of the top portion; a cooling channel disposed on the top surface of the top portion and arranged concentric with the first heating element and between the first heating element and the second and third heating elements; and a bottom portion arranged adjacent to the top portion and comprising: a plurality of first through-holes in fluid communication with the inlet; a plurality of second through-holes in fluid communication with the exhaust plenum; and a plurality of fourth heating elements embedded along an outer edge of the bottom portion and arranged equidistance from each other.

In one embodiment, each of the second and third heating elements is a circular arc shape.

In one embodiment, each of the fourth heating elements comprises a resistive cartridge heater and has length in the range of 25-35 mm and a diameter in the range of 6-7 mm.

In one embodiment, each of the second and third heating elements are arranged directly above and in horizontal alignment with the exhaust plenum.

In one embodiment, the first heating element is arranged directly above the inlet plenum.

In one embodiment, the inlet comprises a first opening at the top surface and having a first diameter; a second opening at the bottom surface and having a second diameter, wherein the second diameter is larger than the first diameter.

In one embodiment, the top portion further comprises a contact area surrounding the second opening of the inlet, wherein the contact area is defined by the bottom surface of the top portion that directly contacts a top surface of the bottom portion and is directly adjacent to and radially outward from the second opening of the inlet.

In one embodiment, the top portion further comprises a groove within the bottom surface of the top portion, radially outward from the contact point, and surrounding the inlet.

In one embodiment, the cooling channel is arranged directly above the contact area and is configured to flow a cooling liquid.

In one embodiment, the plurality of fourth heating elements comprises at least 8 heating elements.

In another aspect, an apparatus comprises: a top portion, comprising: a first top surface and a first bottom surface; an inlet comprising a first opening at the top surface and a second opening at the bottom surface; an exhaust plenum surrounding the inlet; and a thermal system embedded within the top portion and comprising a plurality of circular arc shaped heating elements arranged along an edge of the top surface of the top portion; a cooling channel disposed on the first top surface; and a bottom portion arranged adjacent to the top portion and comprising: a second top surface and a second bottom surface; a plurality of inlet through-holes in fluid communication with the inlet plenum extending between the second top surface and the second bottom surface; a plurality of exhaust through-holes in fluid communication with the exhaust plenum; and a plurality of fourth heating elements embedded along an outer edge of the bottom portion and arranged radially outward from the plurality of exhaust through-holes and equidistance from each other.

In one embodiment, the thermal system comprises: a first heating element arranged in a circular pattern concentric with the first opening of the inlet; second heating element arranged along an edge of the top portion; and a third heating element opposite the second heating element along the edge of the top portion.

In one embodiment, the first opening at the top surface has a first diameter and the second opening at the bottom surface has a second diameter, wherein the second diameter is larger than the first diameter.

In one embodiment, the top portion further comprises: a contact area surrounding the second opening of the inlet plenum, wherein the contact area is defined by the first bottom surface that directly contacts the second top surface and is directly radially outward from the inlet; and a groove within the first bottom surface, radially outward from the contact point, and surrounding the inlet.

In one embodiment, the cooling channel is disposed directly above and horizontally aligned with the contact area.

In yet another aspect, a system comprises: a gas channel plate comprising: a first top surface; a first bottom surface comprising a contact area; an inlet plenum comprising a first opening at the first top surface and a second opening at the first bottom surface, wherein the contact area is radially outward from the second opening; an exhaust plenum surrounding the inlet; and a thermal system comprising: a first heating element arranged in a circular pattern within a first groove in the first top surface; a second heating element arranged within a second groove in the first top surface and along an edge of the gas channel plate; a third heating element arranged within the second groove and along the edge of the gas channel plate opposite the second heating element; and a third groove within the first bottom surface, radially outward from the second opening of the inlet plenum; a showerhead plate adjacent to the gas channel plate and comprising: a second top surface and a second bottom surface; a plurality of inlet through-holes in fluid communication with the inlet plenum; a plurality of exhaust through-holes in fluid communication with the exhaust plenum; and a plurality of fourth heating elements embedded along an outer edge of the bottom portion and arranged equidistance from each other and radially outward from the exhaust through-holes; wherein the second top surface of the showerhead directly contacts the first bottom surface at the contact area on the gas channel plate; a cooling channel arranged concentric with the first heating element and directly above and horizontally aligned with the contact area; and a reaction chamber disposed below the showerhead plate.

In one embodiment, each of the second and third heating elements is a circular arc shape.

In one embodiment, the second heating element has a first wattage and the third heating element has a second wattage that is less than the first wattage.

In one embodiment, the system further comprises a secondary cooling ring disposed along an edge of the showerhead plate between the showerhead plate and the reaction chamber, wherein the secondary cooling ring comprises a channel configured to flow a liquid.

In one embodiment, each of the fourth heating elements comprises a resistive cartridge heater and has length in the range of 25-35 mm and a diameter in the range of 6-7 mm; and the plurality of fourth heating elements comprises at least 8 heating elements.

### BRIEF DESCRIPTION OF THE DRAWING FIGURES

A more complete understanding of the present technology may be derived by referring to the detailed description when considered in connection with the following illustrative figures. In the following figures, like reference numbers refer to similar elements and steps throughout the figures.

FIG. 1 representatively illustrates a system in accordance with embodiments of the present technology;

FIG. 2 is a cross-sectional view of a portion of a reactor in accordance with embodiments of the present technology;

FIG. 3 is a top view of a gas channel plate in accordance with embodiments of the present technology;

FIG. 4 is a bottom view of the gas channel plate in accordance with embodiments of the present technology;

FIG. 5 is a top view of a gas channel plate in accordance with embodiments of the present technology;

FIG. 6 is a top view of the showerhead plate in accordance with embodiments of the present technology;

FIG. 7 is perspective view of a cooling ring in accordance with embodiments of the present technology; and

FIG. 8 is a cross-sectional view of the cooling ring in accordance with embodiments of the present technology.

### DETAILED DESCRIPTION OF EXEMPLARY EMBODIMENTS

The present technology may be described in terms of functional block components and various processing steps. Such functional blocks may be realized by any number of components configured to perform the specified functions and achieve the various results. For example, the present technology may employ various gas lines, valves, controllers, reaction chambers, vessels, and susceptors.

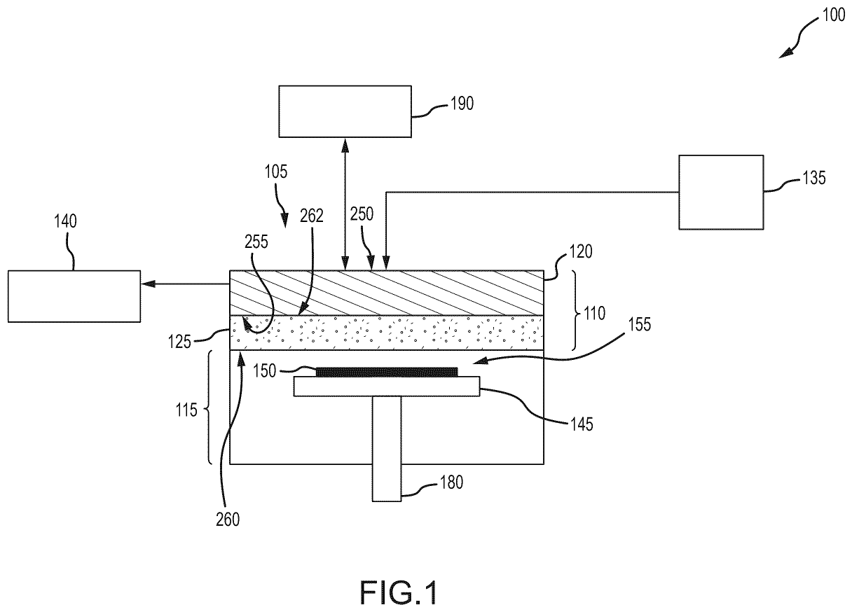

Referring to FIG. 1, an exemplary system 100 may comprise a reactor 105 configured to perform processing on an object to be processed, such as a substrate 150 (e.g., a wafer). For example, the reactor 105 may be configured to perform heating, deposition, etching, polishing, ion implantation, and/or other processing on the object to be processed. In some embodiments, the reactor 105 may be configured to perform a movement function, a vacuum sealing function, an exhaust function. In some embodiments, the reactor 105 may perform an atomic layer deposition (ALD) process or a chemical vapor deposition (CVD) process.

In an exemplary embodiment, the reactor 105 may comprise a reaction chamber 115 comprising a reaction space 155 above and/or around the substrate 150. For example, the reaction chamber 115 may comprise sidewalls and a bottom coupled to the sidewalls that form an enclosed volume.

In various embodiments, the system 100 may further comprise a substrate mounting unit disposed within the reaction chamber 115 of the reactor 105. The substrate mounting unit may comprise a susceptor 145 for supporting the substrate 150 and a heater (not shown) for heating the substrate 150 supported by the susceptor 145. The heater may be embedded within the susceptor 145. The substrate mounting unit may further comprise a pedestal 180 to support the susceptor 145. For loading/unloading of the substrate, the substrate mounting unit may be configured to be vertically movable (up and down) by being connected to a driving unit (not shown). The susceptor 145 may be disposed in or adjacent to the reaction space 155. For example, the susceptor 145 may be arranged to position the substrate 150 in the reaction space 155.

In various embodiments, the system 100 may further comprise a vessel 135 configured to contain a chemical (i.e., a precursor). The vessel 135 may be configured to hold a solid or a liquid chemical, and may further be configured to transform the solid or liquid into a vapor. The vessel 135 may be coupled to the gas distribution system 110. For example, the system 100 may further comprise various gas conduits and/or valves to flow the vapor from the vessel 135 into the gas distribution system 110.

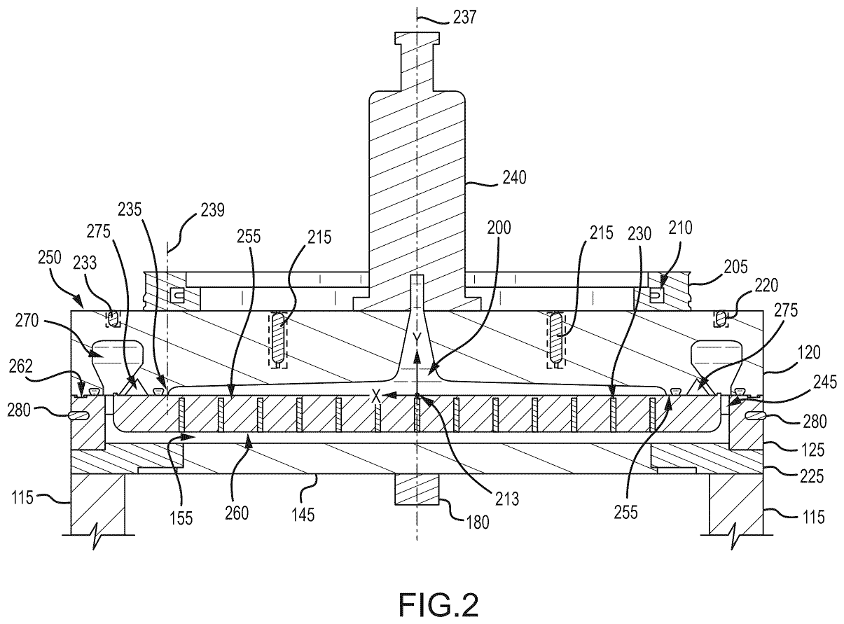

In various embodiments, and referring to FIGS. 1 and 2, the reactor 105 may further comprise a gas distribution system 110 for delivering a vapor into the reaction chamber 115. In an exemplary embodiment, the gas distribution system 110 is arranged above the susceptor 145. The gas distribution system 110 may comprise a top portion 120 (i.e., a gas channel plate) and a bottom portion 125 (i.e., a showerhead plate). The top and bottom portions 120, 125 may be in direct contact with each other. For example, the top portion 120 may comprise a first surface 250 and an opposite, parallel second surface 255, and the bottom portion 125 may comprise a first surface and an opposing, parallel second surface 260. A surface (e.g., the second surface 255) of the top portion 120 may be direct contact with a surface (e.g., the first surface 262) of the bottom portion 125. In some embodiments, the first and second portions 120, 125 may be coupled together with a fastener (not shown), such as a screw or the like.

In various embodiments, the gas distribution system 110 may be arranged adjacent to the reaction chamber 115. For example, the gas distribution system 110 may be arranged on the sidewalls of the reaction chamber 115, opposite the bottom of the reaction chamber 115. In some embodiments, the gas distribution system 110 may be fastened to the sidewalls, however, in other cases, the gas distribution system 110 may merely rest on the sidewalls of the reaction chamber 115. In various embodiments, the gas distribution system 110 together with the reaction chamber 115 sidewalls form an enclosed space, including the reaction space 155.

In some embodiments, the system 100 may further comprise a spacer pate 225 disposed between the gas distribution system 110 and the reaction chamber 115.

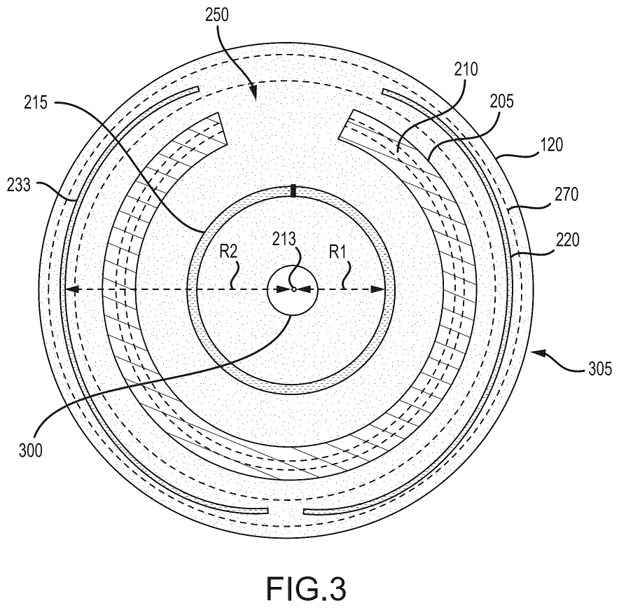

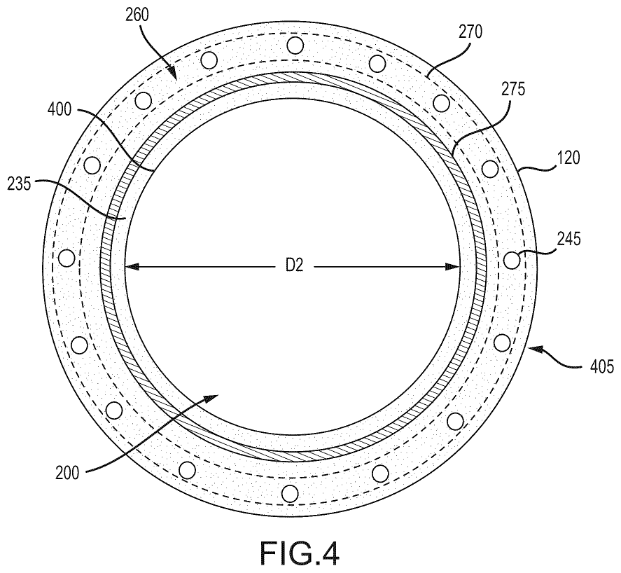

In various embodiments, and referring to FIGS. 2-4, the top portion 120 may comprise an inlet plenum 200 that is fluidly coupled to a valve manifold 240. In various embodiments, the valve manifold 240 is coupled, for example via gas lines, to the vessel 135, and the inlet plenum 200 may deliver a vapor into the reaction space 155. The inlet plenum 200 may comprise an inlet opening 300 having a diameter D1 and an outlet opening 400 having a diameter D2, wherein D2 is larger than D1.

In various embodiments, the top portion 120 may further comprise an exhaust plenum 270 coupled to an exhaust system 140. The exhaust plenum 270 may comprise an inlet at the second surface 255 and an outlet that is fluidly coupled to the exhaust system 140. For example, gas may flow from the plenum 270 through the respective outlets and into the exhaust system 140. In various embodiments, the exhaust plenum 270 may be arranged concentric with the inlet plenum 200. For example, the exhaust plenum 270 may have a ring shape with a diameter that surrounds and is larger than the inlet plenum 200.

In various embodiments, the top portion 120 may comprise a thermal system. For example, the thermal system may comprise a first heating element 215, a second heating element 233, and a third heating element 220. Each heating element may be embedded within the top portion 120. For example, the first heating element 215 may be disposed within a groove on the first surface 250 of the top portion 120. The first heating element 215 may be formed in the shape of a substantially continuous ring and have a diameter D3 and a radius R1 (from a center point 213) in the range of 80 mm to 115 mm, for example a radius of 97 mm. The first heating element 215 may be disposed directly above the inlet plenum 200 and concentric with the center point 213 of the inlet plenum 200 and the inlet opening 300. The first heating element 215 may comprise a resistive-type heater or any other suitable heating element or heating system.

In various embodiments, the second heating element 233 may be disposed along an edge 305 of the top portion 120 and embedded within the top portion. For example, the second heating element 233 may be disposed within a groove along the outer edge 305. In an exemplary embodiment, the second heating element 233 may have a circular arc shape that spans across a first half of the top portion 120. The second heating element 233 may comprise a resistive-type heater or any other suitable heating element or heating system. In an exemplary embodiment, the second heating element 233 is a single heating element configured to operate at a first wattage and at a first temperature.

In various embodiments, the third heating element 220 may be disposed along an edge of the top portion 120 that is opposite the second heating element 233. The third heating element 220 may be disposed within a groove along the outer edge 305 that is opposite the second heating element 233. In an exemplary embodiment, the third heating element 220 may have a circular arc shape that spans across a second half of the top portion 120. The third heating element 215 may comprise a resistive- type heater or any other suitable heating element or heating system. In an exemplary embodiment, the third heating element 220 is a single heating element configured to operate a second wattage and at a second temperature. The second wattage may be higher than the first wattage, and therefore, the third heating element 220 may be configured to operate at a higher temperature than the second heating element 233.

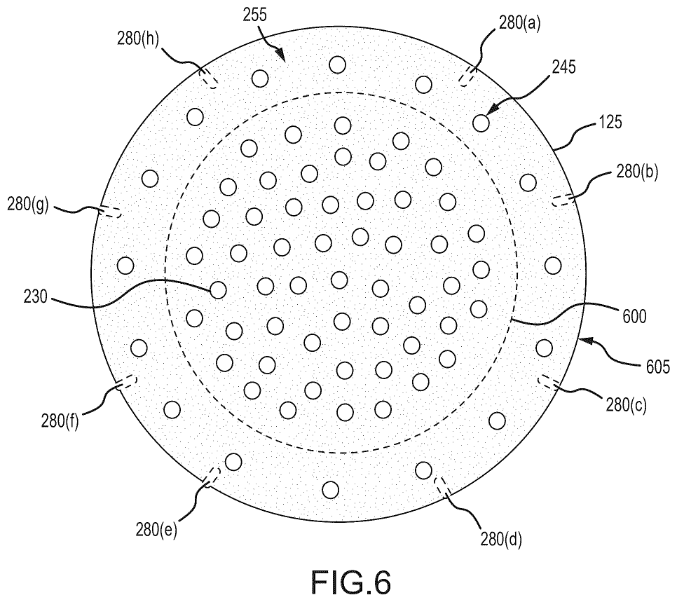

In various embodiments, the second and third heating elements 233, 220 may be arranged directly above the exhaust plenum 270 and radially outward from the first heating element 215, the cooling channel 210, and the showerhead region 600 (FIG. 6). In an exemplary embodiment, the second and third heating elements 233, 220 may have a radius R2 in the range of 180 mm to 240 mm, for example 200 mm, from the center point 213.

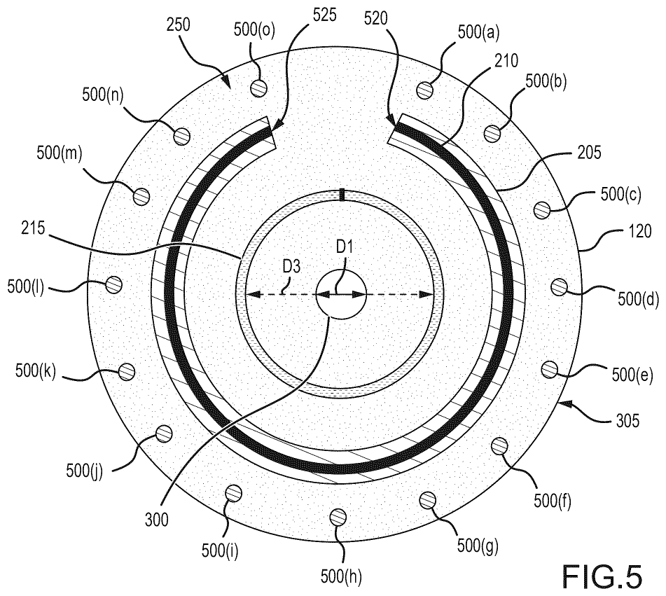

In an alternative embodiment, and referring to FIG. 5, the thermal system may comprise a plurality of heating rods 500, such as heating rods 500(a)-500(o) disposed along the edge 305 of the top portion 120. In the present embodiment, the heating rods 500(a)-500(o) may be embedded within the top portion 120. For example, the heating rods 500 may be disposed within cavities along the first surface 250 of the top portion 120. In the present embodiment, each heating rod may be controlled independently from the other heating rods. Alternatively, two or more adjacent heating rods (e.g., 500(a) and 500(b)) may be controlled independently from a different two or more adjacent heating rods (e.g., 500(m) and 500(n).

In various embodiments, and referring back to FIGS. 2-4, the top portion 120 may further comprise a contact area 235 directly adjacent to the outlet opening 400 of the inlet plenum 200. The second surface 255 of the top portion 120 may comprise the contact area 235, and the contact area 235 may directly contact the first surface 262 of the bottom portion 125. In other words, the contact area is defined by the bottom surface 255 of the top portion 120 that directly contacts the top surface 262 of the bottom portion 125 and is directly adjacent to and radially outward from the outlet opening 400 of the inlet plenum 200.

In various embodiments, the top portion 120 may further comprise a channel 275 within the second surface 255. In an exemplary embodiment, the channel 275 may be circular-shaped and surround the outlet opening 400 of the inlet plenum 200. The channel 275 may be disposed between the contact area 235 and the exhaust plenum 270.

In various embodiments, and referring to FIGS. 2, 3, and 5, the system 100 may further comprise a cooling ring 205. The cooling ring 205 may be affixed to the first surface 250 of the top portion 120. The cooling ring 205 may be formed from a metal material, such as elemental aluminum, stainless steel, or any other metal or metal alloy. The cooling ring 205 may comprise a channel 210, disposed within the ring 205, and configured to flow a liquid, such as a water or any other suitable cooling liquid, from a first end 520 to a second end 525. In an exemplary embodiment, the cooling ring 205 may have a circular shape, such as a C-shape or arc shape. In an exemplary embodiment, the cooling ring 205 may be arranged directly above and vertically aligned with the contact area 235. For example, the channel 210 and the contact area 235 may be aligned along an imaginary vertical line 239, and the channel 210 and the contact area 235 may be disposed at a substantially equal distance from a center axis 237. In an exemplary embodiment, a diameter of the cooling ring 205 may be substantially the same (e.g., +/−5 mm) as the diameter D2 of the outlet opening 400 of the inlet plenum 200.

In various embodiments, the bottom portion 125 may comprise a plurality of inlet through-holes 230 that extend through the first surface 262 and the second surface 260. The plurality of inlet through-holes 230 may contain approximately 1000-1200 through-holes. The plurality of inlet through-holes 230 may be arranged within a central region 600 (FIG. 6; also referred to as a showerhead region) of the bottom portion 125. The inlet plenum 200 may be in fluid communication with the plurality of inlet through-holes 230. For example, the vapor that flows into the inlet plenum 200 from the vessel 135 may continue to flow through the plurality of through-holes 230. The plurality of inlet through-holes 230 may be in fluid communication with the reaction space 155. For example, the vapor may flow through the plurality of inlet through-holes 230 and into the reaction space 155.

In various embodiments, and referring to FIG. 6, the bottom portion 125 may further comprise a plurality of exhaust through-holes 245, wherein each exhaust through-hole may have a first opening at the first surface 262 of the bottom portion 125 and a second opening adjacent to the reaction space 155. For example, the plurality of exhaust through-holes 245 may be arranged radially outward from the central region 600. In addition, the first openings of the plurality of second exhaust through-holes 245 may be positioned to be in fluid communication with the exhaust plenum 270. In particular, the first openings of the plurality of exhaust through-holes 245 may align with the inlet of the exhaust plenum 270. In an exemplary embodiment, each exhaust through-hole 245 may be vertically oriented within the bottom portion 125.

In various embodiments, and referring to FIGS. 2 and 6, the bottom portion 125 may further comprise a plurality of fourth heating elements 280. The plurality of fourth heating elements 280 may be inserted into a bore along the outer edge 605 of the bottom portion 125. The fourth heating elements 280 may be arranged at equal arc lengths around the bottom portion 125. In various embodiments, each of the fourth heating elements 280 may comprise a resistive cartridge heater and has length in the range of 25-35 mm and a diameter in the range of 6-7 mm. In various embodiments, the plurality of fourth heating elements comprises at least 4 heating elements, at in particular, at least 8 heating elements.

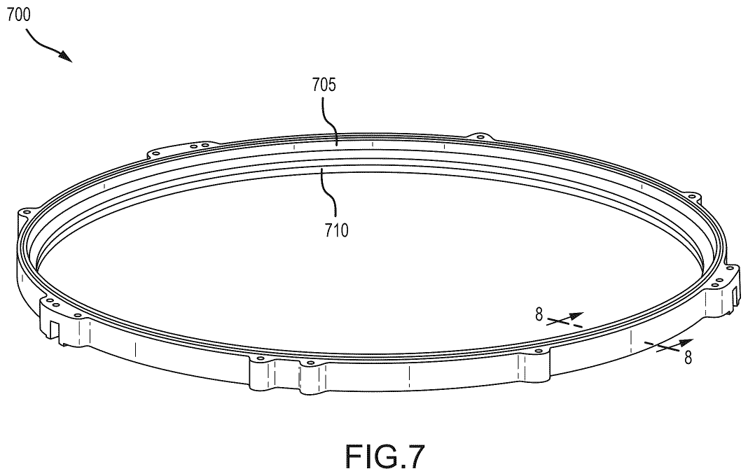

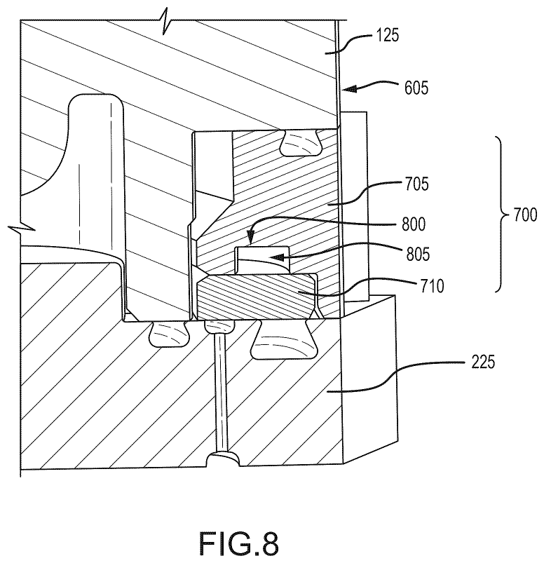

In various embodiments, and referring to FIGS. 7 and 8, the system 100 may further comprise a secondary cooling ring 700. The secondary cooling ring 700 may be disposed between the bottom portion 125 and the spacer plate 225 along the outer edge of the spacer plate 225 and the bottom portion 125. In an exemplary embodiment, the secondary cooling ring 700 may comprise a first part 705 and a second part 710 that are affixed to each other, for example by welding. The first part 705 may comprise a groove 800 formed along a downward facing surface. The second part 710 may be affixed to the downward facing surface. The second part 710 and the groove 800 of the first part 705 may form an enclosed channel 805 configured to flow a liquid, such as water. In an exemplary embodiment, the enclosed channel 805 may have a height in the range of 2 mm to 5 mm and a width in the range of 3 mm to 7 mm. In various embodiments, the secondary cooling ring 700 may be formed from elemental aluminum, stainless steel, or any other suitable metal or metal alloy.

In various embodiments, and referring to FIGS. 1-8, the system 100 may further comprise a controller 190 configured to control operation of various components within the system, such as the thermal system, and in particular the first heating element 215, the second heating element 233, the third heating element 220, the plurality of fourth heating elements 280, and/or the plurality of heating rods 500(a)-500(o). For example, the controller 190 may be electrically and/or commutatively coupled to the first heating element 215, the second heating element 233, the third heating element 220, the plurality of fourth heating elements 280, and/or the plurality of heating rods 500(a)-500(o), and the controller 190 may transmit a control signal to each one that indicates a desired temperature.

The controller 190 may also receive information, data, or signals from other components, such as temperature data/signals from a temperature sensor (not shown), and the controller 190 may operate the heating elements (e.g., the first heating element 215, the second heating element 233, the third heating element 220, the plurality of fourth heating elements 280, and/or the plurality of heating rods 500(a)-500(o)) based on a measured temperature from the temperature sensor. For example, the controller 190 may receive a measured temperature from the temperature sensor and determine if the measured temperature is at a desired temperature or within a desired temperature range. If the measured temperature is not at the desired temperature or temperature range, the controller 190 may transmit a signal to one or more of the heating elements (e.g., the first heating element 215, the second heating element 233, the third heating element 220, the plurality of fourth heating elements 280, and/or the plurality of heating rods 500(a)-500(o)).

In various embodiments, the controller 190 may also initiate and/or control, via for example, a valve (not shown), flow of the liquid through the channel 210 of the cooling ring 205 and/or the enclosed channel 805 of the secondary cooling ring 700. For example, the controller 190 may determine that the measured temperature is not within the desired range and initiate a control signal to adjust the flow of the liquid to maintain the desired temperature.

In the foregoing description, the technology has been described with reference to specific exemplary embodiments. The particular implementations shown and described are illustrative of the technology and its best mode and are not intended to otherwise limit the scope of the present technology in any way. Indeed, for the sake of brevity, conventional manufacturing, connection, preparation, and other functional aspects of the method and system may not be described in detail. Furthermore, the connecting lines shown in the various figures are intended to represent exemplary functional relationships and/or steps between the various elements. Many alternative or additional functional relationships or physical connections may be present in a practical system.

The technology has been described with reference to specific exemplary embodiments. Various modifications and changes, however, may be made without departing from the scope of the present technology. The description and figures are to be regarded in an illustrative manner, rather than a restrictive one and all such modifications are intended to be included within the scope of the present technology. Accordingly, the scope of the technology should be determined by the generic embodiments described and their legal equivalents rather than by merely the specific examples described above. For example, the steps recited in any method or process embodiment may be executed in any order, unless otherwise expressly specified, and are not limited to the explicit order presented in the specific examples. Additionally, the components and/or elements recited in any apparatus embodiment may be assembled or otherwise operationally configured in a variety of permutations to produce substantially the same result as the present technology and are accordingly not limited to the specific configuration recited in the specific examples.

Benefits, other advantages and solutions to problems have been described above with regard to particular embodiments. Any benefit, advantage, solution to problems or any element that may cause any particular benefit, advantage or solution to occur or to become more pronounced, however, is not to be construed as a critical, required or essential feature or component.

The terms “comprises”, “comprising”, or any variation thereof, are intended to reference a non-exclusive inclusion, such that a process, method, article, composition or apparatus that comprises a list of elements does not include only those elements recited, but may also include other elements not expressly listed or inherent to such process, method, article, composition or apparatus. Other combinations and/or modifications of the above-described structures, arrangements, applications, proportions, elements, materials or components used in the practice of the present technology, in addition to those not specifically recited, may be varied or otherwise particularly adapted to specific environments, manufacturing specifications, design parameters or other operating requirements without departing from the general principles of the same.

The present technology has been described above with reference to an exemplary embodiment. However, changes and modifications may be made to the exemplary embodiment without departing from the scope of the present technology. These and other changes or modifications are intended to be included within the scope of the present technology, as expressed in the following claims.

What is claimed is:

1. An apparatus, comprising:
a top portion comprising:
a top surface and a bottom surface;
an inlet extending between the top surface and the bottom surface;
an exhaust plenum surrounding the inlet; and
a thermal system embedded within the top portion and comprising:
a first heating element arranged in a circular pattern concentric with the inlet;
a second heating element arranged along an edge of the top portion; and
a third heating element opposite the second heating element along the edge of the top portion;
a cooling channel disposed on the top surface of the top portion and arranged concentric with the first heating element and between the first heating element and the second and third heating elements; and
a bottom portion arranged adjacent to and directly below the top portion and comprising:
a plurality of first through-holes in fluid communication with the inlet;
a plurality of second through-holes in fluid communication with the exhaust plenum; and
a plurality of fourth heating elements embedded along an outer edge of the bottom portion and arranged equidistance from each other.

2. The apparatus according to claim 1, wherein each of the second and third heating elements is a circular arc shape.

3. The apparatus according to claim 1, wherein each of the fourth heating elements comprises a resistive cartridge heater and has length in the range of 25-35 mm and a diameter in the range of 6-7 mm.

4. The apparatus according to claim 1, wherein each of the second and third heating elements are arranged directly above and in horizontal alignment with the exhaust plenum.

5. The apparatus according to claim 1, wherein the first heating element is arranged directly above the inlet plenum.

6. The apparatus according to claim 1, wherein the inlet comprises a first opening at the top surface and having a first diameter; a second opening at the bottom surface and having a second diameter, wherein the second diameter is larger than the first diameter.

7. The apparatus according to claim 6, wherein the top portion further comprises a contact area surrounding the second opening of the inlet, wherein the contact area is defined by the bottom surface of the top portion that directly contacts a top surface of the bottom portion and is directly adjacent to and radially outward from the second opening of the inlet.

8. The apparatus according to claim 7, wherein the top portion further comprises a groove within the bottom surface of the top portion, radially outward from the contact point, and surrounding the inlet.

9. The apparatus according to claim 7, wherein the cooling channel is arranged directly above the contact area and is configured to flow a cooling liquid.

10. The apparatus according to claim 1, wherein the plurality of fourth heating elements comprises at least 8 heating elements.

11. An apparatus, comprising:
a top portion, comprising:
a first top surface and a first bottom surface;
an inlet comprising a first opening at the top surface and a second opening at the bottom surface;
an exhaust plenum surrounding the inlet; and
a thermal system embedded within the top portion and comprising a plurality of circular arc shaped heating elements arranged along an edge of the top surface of the top portion;
a cooling channel disposed on the first top surface; and
a bottom portion arranged adjacent to the top portion and comprising:
a second top surface and a second bottom surface;
a plurality of inlet through-holes in fluid communication with the inlet plenum extending between the second top surface and the second bottom surface;
a plurality of exhaust through-holes in fluid communication with the exhaust plenum; and
a plurality of fourth heating elements embedded along an outer edge of the bottom portion and arranged radially outward from the plurality of exhaust through-holes and equidistance from each other.

12. The apparatus according to claim 11, wherein the thermal system comprises:
a first heating element arranged in a circular pattern concentric with the first opening of the inlet;
second heating element arranged along an edge of the top portion; and
a third heating element opposite the second heating element along the edge of the top portion.

13. The apparatus according to claim 11, wherein the first opening at the top surface has a first diameter and the second opening at the bottom surface has a second diameter, wherein the second diameter is larger than the first diameter.

14. The apparatus according to claim 11, wherein the top portion further comprises:
a contact area surrounding the second opening of the inlet plenum, wherein the contact area is defined by the first bottom surface that directly contacts the second top surface and is directly radially outward from the inlet; and
a groove within the first bottom surface, radially outward from the contact point, and surrounding the inlet.

15. The apparatus according to claim 14, wherein the cooling channel is disposed directly above and horizontally aligned with the contact area.

16. A system, comprising:
a gas channel plate comprising:
a first top surface;
a first bottom surface comprising a contact area;
an inlet plenum comprising a first opening at the first top surface and a second opening at the first bottom surface, wherein the contact area is radially outward from the second opening;
an exhaust plenum surrounding the inlet; and
a thermal system comprising:
a first heating element arranged in a circular pattern within a first groove in the first top surface;
a second heating element arranged within a second groove in the first top surface and along an edge of the gas channel plate;
a third heating element arranged within the second groove and along the edge of the gas channel plate opposite the second heating element; and
a third groove within the first bottom surface, radially outward from the second opening of the inlet plenum;
a showerhead plate adjacent to the gas channel plate and comprising:
a second top surface and a second bottom surface;
a plurality of inlet through-holes in fluid communication with the inlet plenum;
a plurality of exhaust through-holes in fluid communication with the exhaust plenum; and
a plurality of fourth heating elements embedded along an outer edge of the bottom portion and arranged equidistance from each other and radially outward from the exhaust through-holes;
wherein the second top surface of the showerhead directly contacts the first bottom surface at the contact area on the gas channel plate;
a cooling channel arranged concentric with the first heating element and directly above and horizontally aligned with the contact area; and
a reaction chamber disposed below the showerhead plate.

17. The system according to claim 16, wherein each of the second and third heating elements is a circular arc shape.

18. The system according to claim 16, wherein the second heating element has a first wattage and the third heating element has a second wattage that is less than the first wattage.

19. The system according to claim 16, further comprising a secondary cooling ring disposed along an edge of the showerhead plate between the showerhead plate and the reaction chamber, wherein the secondary cooling ring comprises a channel configured to flow a liquid.

20. The system according to claim 16, wherein:
each of the fourth heating elements comprises a resistive cartridge heater and has length in the range of 25-35 mm and a diameter in the range of 6-7 mm; and
the plurality of fourth heating elements comprises at least 8 heating elements.
